(19) United States
(12) Patent Application Publication
(10) Pub. No.: US 2024/0136797 A1
(43) Pub. Date: Apr. 25, 2024

(54) Vertical Cavity Surface Emitting Laser and Manufacturing Method Thereof

(71) Applicant: Shenzhen Berxel Photonics Co., Ltd., Shenzhen City (CN)

(72) Inventors: Jiaxing WANG, Shenzhen City (CN); Sui ZHANG, Shenzhen City (CN)

(21) Appl. No.: 18/132,414

(22) Filed: Apr. 8, 2023

(30) Foreign Application Priority Data
Oct. 19, 2022 (CN) 202211292084.1

(51) Int. Cl. H01S 5/183

(52) U.S. Cl. CPC H01S 5/18377; H01S 5/18311

(57) ABSTRACT

Provided are a vertical cavity surface emitting laser and a manufacturing method thereof, the vertical cavity surface emitting laser comprises a laser precursor, and the laser precursor comprises a first reflector layer, an oxidation layer, a light-emitting layer and a second reflector layer which are stacked, wherein the second reflector layer comprises a plurality of first reflection layers and a plurality of second reflection layers, and a groove is formed on the side of the second reflection layer from the oxidation groove and in a direction away from the oxidation groove; a protection layer is arranged on the laser precursor, and the protection layer at least covers the inner wall of the oxidation groove, and the groove is filled with a part of the protection layer. The technical solution may avoid the collapse of the edge of the first reflection layer.

### CROSS REFERENCE TO RELATED APPLICATION

The present disclosure claims the benefit of priority to Chinese patent application No. 202211292084.1, filed on Oct. 20, 2022 to China National Intellectual Property Administration, which is incorporated herein by reference in its entirety.

### TECHNICAL FIELD

The present disclosure generally relates to the field of laser technology, in particular, to a vertical cavity surface emitting laser and a manufacturing method thereof.

### BACKGROUND

A vertical cavity surface emitting laser (VCSEL) comprises a positive electrode, a first reflector layer, a light-emitting layer, an oxidation layer, a second reflector layer, and a negative electrode. When the positive and negative electrodes are connected to a power supply, a current circuit is formed among the positive electrode, the first reflector layer, the light-emitting layer, the second reflector layer and the negative electrode so as to allow the light-emitting layer to luminesce.

Generally, the second reflector layer comprises a first reflection layer and a second reflection layer which are stacked, and the aluminum content of the second reflection layer is greater than that of the first reflection layer. This results in a groove forming on the edge of the second reflection layer during manufacturing, and causes the edge of the first reflection layer to be suspending, thereby causing a collapse of the edge of the first reflection layer.

### SUMMARY OF INVENTION

In the present disclosure, it is desired to provide a vertical cavity surface emitting laser and a manufacturing method thereof, so as to at least solve the problem of collapse of the edge of the first reflection layer.

In a first aspect, the present disclosure provides a vertical cavity surface emitting laser comprising:
A laser precursor, wherein the laser precursor comprises a first reflector layer, an oxidation layer, a light-emitting layer and a second reflector layer which are stacked, the laser precursor comprises two or more light-emitting regions, an oxidation groove is provided between at least adjacent light-emitting regions, the oxidation groove cuts through at least from the top of the laser precursor to the top of the first reflector layer;
The second reflector layer comprises a plurality of first reflection layers and a plurality of second reflection layers, the first reflection layers and the second reflection layers are stacked alternately, and a groove is formed on the side of the second reflection layer from the oxidation groove and in a direction away from the oxidation groove;
A protection layer, which is arranged on the laser precursor, and the protection layer at least covers the inner wall of the oxidation groove, and the groove is filled with a part of the protection layer.

As a realizable way, the groove is fully filled with the protection layer.

As a realizable way, the protection layer is a silica protection layer or a silicon nitride protection layer.

As a realizable way, both the first reflection layer and the second reflection layer are aluminum gallium arsenide reflection layers, and the aluminum content of the second reflection layer is greater than that of the first reflection layer.

As a realizable way, the oxidation layer comprises an unoxidized region and an oxidized region surrounding the unoxidized region, the unoxidized region is arranged in one-to-one correspondence with the light emitting region;

In the depth direction of the groove, the depth of the groove is less than the oxidation depth of the oxidation region.

As a realizable way, the depth of each groove is the same or different.

As a realizable way, the thickness of each first reflective layer is the same or different, and the thickness of each second reflective layer is the same or different.

In a second aspect, the present disclosure provides a manufacturing method for the vertical cavity surface emission laser, comprising the following steps:
Providing a laser precursor, wherein the laser precursor comprises a first reflector layer, an oxidation layer, a light-emitting layer and a second reflector layer which are stacked, the laser precursor comprises two or more light-emitting regions; the second reflector layer comprises a plurality of first reflection layers and a plurality of second reflection layers, and the first reflection layers and the second reflection layers are stacked alternately;
Forming an oxidation groove between at least adjacent light-emitting regions by etching, wherein the oxidation groove cuts through at least from the top of the laser precursor to the top of the first reflector layer;
Performing oxidation on the oxidation layer in the oxidation groove, so as to form an unoxidized region and an oxidized region surrounding the unoxidized region, and forming a groove on the side of the second reflection layer, from the oxidation groove and in a direction away from the oxidation groove;
Arranging a protection layer on the laser precursor through an vapor deposition process, the protection layer at least covers the inner wall of the oxidation groove, and the groove is filled with a part of the protection layer. In the vapor deposition process, the operation temperature is from 180° C. to 220° C., and the operation pressure is 0 hPa-1 hPa (one hundred Pa).

In the above technical solutions, by arranging a protection layer, it allows the groove to be filled with a part of the protection layer, and thus this part of the protection layer which fills the groove may support the edge of an adjacent first reflection layer. Therefore, it avoids problems relating to the suspension and collapse of the first reflection layer at the edge thereof caused by the formation of a groove at the edge of the second reflection layer.

### BRIEF DESCRIPTION OF FIGURES

By reading detailed descriptions of nonrestrictive embodiments with reference to the accompanying drawings, other features, objectives and advantages of the present disclosure will become more apparent.

FIG. 1 is a structural diagram of a vertical cavity surface emitting laser provided in an embodiment of the present disclosure.

FIG. 2 is a flow diagram of a manufacturing method for a vertical cavity surface emitting laser provided in an embodiment of the present disclosure.

FIG. 3 is a structural schematic diagram of the manufacturing process of a vertical cavity surface emitting laser provided in an embodiment of the present disclosure.

FIG. 4 is an enlarged microscopic view of an oxidation groove of a vertical cavity surface emitting laser provided in an embodiment of the present disclosure.

FIG. 5 is an enlarged view of portion I after forming a protection layer.

### DETAILED DESCRIPTION

In the below, the present disclosure shall be further described in details in combination with the attaching drawings and embodiments. It should be understood that the specific embodiments described herein are only used to explain the invention, but not limited to the present invention. In addition, it also needs to illustrate that, for the convenience of reciting the invention, these drawings only show the parts related to the present invention.

It should be noted that, embodiments and features in these embodiments in the present disclosure shall be combined with each other without any conflict conditions. The present disclosure shall be described in details with reference to the attaching drawings and embodiments.

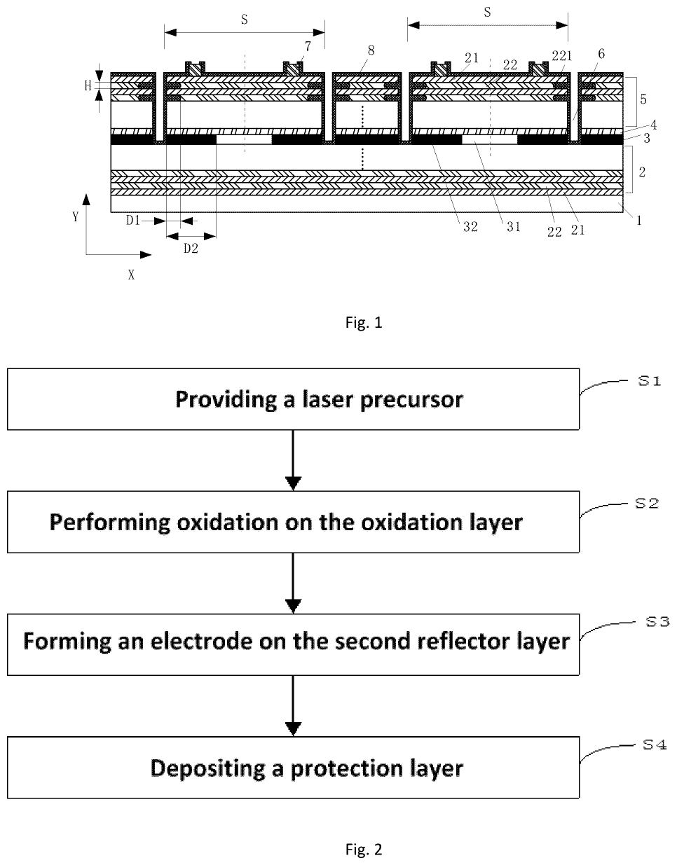

As shown in FIG. 1, embodiments of the present invention provides a vertical cavity surface emitting laser comprising:

A laser precursor, wherein the laser precursor comprises a first reflector layer 2, an oxidation layer 3, a light-emitting layer 4 and a second reflector layer 5 which are stacked, the laser precursor comprises two or more light-emitting regions S, an oxidation groove 6 is provided between at least adjacent light-emitting regions S, the oxidation groove 6 cuts through at least from the top of the laser precursor to the top of the first reflector layer 2.

The phrase “which are stacked” herein means that, each layer for forming the laser precursor are stacked with each other. Each layer may be directly connected, or connected through other layers, and if there are no conflict conditions, the position relationship of the layers may be exchanged. For example, the first reflector layer 2, the oxidation layer 3, the light-emitting layer 4 and the second reflector layer 5 may be stacked as below: the oxidation layer 3 is arranged on the first reflector layer 2, the light-emitting layer 4 is arranged on the oxidation layer 3, and the second reflector layer 5 is arranged on the light-emitting layer 4; alternatively, the light-emitting layer 4 is arranged on the first reflector layer 2, the oxidation layer 3 is arranged on the light-emitting layer 4, and the second reflector layer 5 is arranged on the oxidation layer 3; alternatively, the first oxidation layer is arranged on the first reflector layer 2, the light-emitting layer 4 is arranged on the first oxidation layer, the second oxidation layer is arranged on the light-emitting layer 4, and the second reflector layer 5 is arranged on the second oxidation layer; alternatively, the oxidation layer 3 is arranged on the first reflector layer 2, the light-emitting layer 4 is arranged on the oxidation layer 3, a current explanation layer is arranged on the light-emitting layer 4, and the second reflector 5 is arranged on the current explanation layer, and the like. The above description only introduces some examples, rather than exhaustive examples of the laser precursor.

The second reflector layer 5 comprises a plurality of first reflection layers 21 and a plurality of second reflection layers 22, the first reflection layers 21 and the second reflection layers 22 are stacked alternately, and a groove 221 is formed on the side of the second reflection layer 22 from the oxidation groove 6 and in a direction away from the oxidation groove 6.

For example, but it is not limited to that, the second reflector layer 5 is a distributed Bragg reflector (DBR) layer. For example, but it is not limited to that, the first reflector layer 2 is a layer of Al_{y}Ga_{1-y}As, and the second reflector layer 5 is a layer of AlₓGa₁₋ₓAs, wherein, x>0.7, y<0.4. In the manufacturing process, a groove 221 is formed on the side of the second reflection layer 22 from the oxidation groove 6 and in a direction away from the oxidation groove 6. That is, a groove 221 is formed in X-axis direction in FIG. 1.

A protection layer 8 is arranged on the laser precursor, and the protection layer 8 at least covers the inner wall of the oxidation groove 6, and the groove 221 is filled with a part of the protection layer.

In the above technical solutions, by arranging a protection layer 8, it allows the groove 221 to be filled within a part of the protection layer 8, and thus this part of the protection layer 8 which fills the groove 221 may support the edge of an adjacent first reflection layer 21. Therefore, it avoids problems relating to the suspension and collapse of the first reflection layer 21 at the edge thereof caused by the formation of a groove 221 at the edge of the second reflection layer 22. In addition to a part of the protection layer 8 that fills the groove 221 for preventing from the collapse of the first reflector layer 21, the remaining part may also perform electrical protection on the laser precursor.

As a realizable way, for avoiding the collapse of the edge of the first reflection layer 21 to the greatest extent, the groove 221 is fully filled with the protection layer 8. That is, the whole groove 221 is full of the material forming the protection layer 8, so that the material of the protection layer 8 in the groove 221 may fully support the edge of the first reflection layer 21.

As a realizable way, the protection layer 8 is a silica protection layer or a silicon nitride protection layer. For example, but it is not limited to that, the silica protection layer or the silicon nitride protection layer is formed through a vapor deposition process.

As a realizable way, both the first reflection layer 21 and the second reflection layer 22 are aluminum gallium arsenide reflection layers, and the aluminum content of the second reflection layer 22 is greater than that of the first reflection layer 21. That is, the second reflection layer 22 is a layer having a higher content of aluminum, the first reflection layer 21 is a layer having a lower content of aluminum. During the oxidation process of the oxidation layer, the oxidized part in the second reflection layer 22 shrinks and then forms a groove 221 at the edge thereof, because the second reflection layer 22 having a higher content of aluminum has a higher shrinkage rate.

As a realizable way, the oxidation layer 3 comprises an unoxidized region 31 and an oxidized region 32 surrounding the unoxidized region 31. The unoxidized region 31 is arranged in one-to-one correspondence with the light emitting region S.

In the depth direction of the groove 221, the depth D1 of the groove 221 is less than the oxidation depth D2 of the oxidation region 32.

As a realizable way, the depth D of each groove 221 is the same or different.

As a realizable way, the thickness of each first reflective layer 21 or each second reflective layer 22 is the same or different.

Taking a specific embodiment, the present invention shall be exemplarily described in the following, however, it should be understood that, it is not the only definition.

As shown in FIG. 1, it exemplarily shows a vertical cavity surface emitting laser comprising: a substrate, a first reflector layer 2 arranged on the substrate, an oxidation layer 3 arranged on the first reflector layer 2, an light-emitting layer 4 arranged on the oxidation layer 3, a second reflector layer 5 arranged on the light-emitting layer 4, and electrodes arranged on the light-emitting layer 4, wherein the substrate, the first reflector layer 2, the oxidation layer 3, the light-emitting layer 4 and the second reflector layer 5 constitute a laser precursor. The laser precursor has a plurality of light-emitting regions S, an oxidation groove 6 is provided between adjacent light-emitting regions S, the oxidation groove 6 cuts through at least from the top of the laser precursor to the top of the first reflector layer 2. Both of the first reflector layer 2 and the second reflector layer 5 are distributed Bragg reflectors (DBRs) comprising a plurality of the first reflector and the second reflector which are stacked alternately. In this example, the thickness of the first reflector is the same as that of the second reflector. That is, the dimensions thereof are the same in Y-axis direction. For example, but it is not limited to that, the first reflector layer 2 is a layer of Al_{y}Ga_{1-y}As, and the second reflector layer 5 is a layer of AlₓGa₁₋ₓAs, wherein, x>0.7, y<0.4. In the manufacturing process, a groove 221 is formed on the side of the second reflection layer 22 from the oxidation groove 6 and in a direction away from the oxidation groove 6. That is, a groove 221 is formed in X-axis direction in FIG. 1. A protection layer 8 is arranged on the laser precursor, and the protection layer 8 at least covers the inner wall of the oxidation groove 6, and the groove 221 is filled with a part of the protection layer. In addition, the protection layer 8 exposes the above electrodes.

In this example, the protection layer 8 is a silica protection layer.

The oxidation layer 3 comprises an unoxidized region 31 and an oxidized region 32 surrounding the unoxidized region 31. The unoxidized region 31 is arranged in one-to-one correspondence with the light emitting region S. And in the depth direction of the groove 221, i.e. in X-axis direction, the depth D1 of the groove 221 is less than the oxidation depth D2 of the oxidation region 32. In addition, at least several grooves 221 have different depths.

In a second aspect, the present disclosure provides a manufacturing method for the vertical cavity surface emission laser, including:
Providing a laser precursor, wherein the laser precursor comprises a first reflector layer 2, an oxidation layer 3, a light-emitting layer 4 and a second reflector layer 5 which are stacked, the laser precursor comprises two or more light-emitting regions 5; the second reflector layer 5 comprises a plurality of first reflection layers 21 and a plurality of second reflection layers 22, and the first reflection layer 21 and the second reflection layer 22 are stacked alternately;
Forming an oxidation groove 6 between at least adjacent light-emitting regions S by etching, wherein the oxidation groove cuts through at least from the top of the laser precursor to the top of the first reflector layer 2;
Performing oxidation on the oxidation layer 3 in the oxidation groove 6, so as to form an unoxidized region 31 and an oxidized region 32 surrounding the unoxidized region 31 in the oxidation layer 3, and forming a groove 221 on the side of the second reflection layer 22 from the oxidation groove 6 and in a direction away from the oxidation groove 6;
Arranging a protection layer 8 on the laser precursor through a vapor deposition process, wherein the protection layer 8 at least covers the inner wall of the oxidation groove 6, and the groove 221 is filled with a part of the protection layer. In the vapor deposition process, the operation temperature is from 180° C. to 220° C., and the operation pressure is 0 hPa-1 hPa, so that the groove 221 is fully filled with the material of the protection layer 8.

Taking a specific embodiment, the present invention shall be exemplarily described in the following, however, it should be understood that, it is not the only definition.

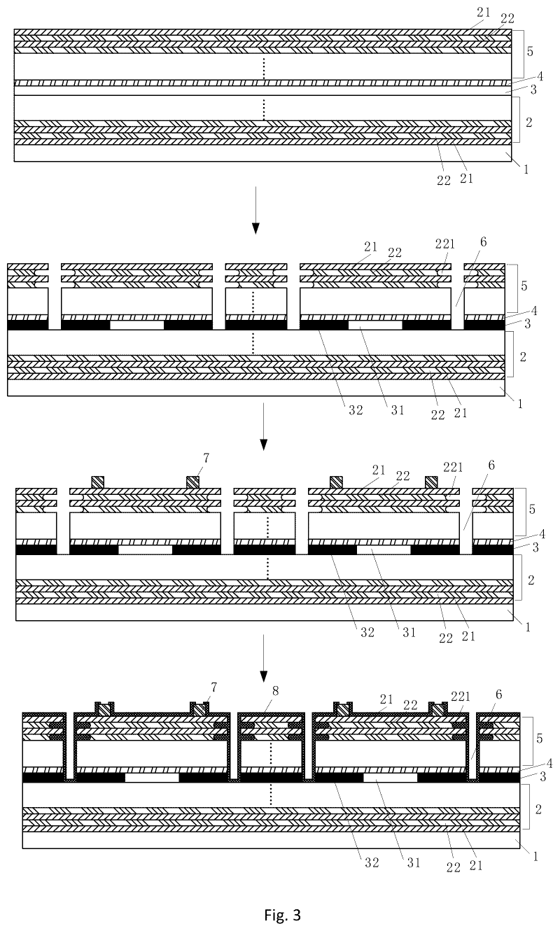

As shown in FIG. 2 and FIG. 3, it exemplarily shows a manufacturing method for a vertical cavity surface emitting laser comprising the following steps:

S1, Providing a laser precursor; for example, it may form the laser precursor by adopting the following processes:
Providing a substrate 1, wherein the substrate 1 may be a GaAs substrate;
Forming a first reflector layer 2 on the substrate 1, wherein the first reflector layer 2 may comprise a first reflection layer 21 and a second reflection layer 22 which are stacked, the specific layer number of the first reflection layer 21 or the second reflection layer 22 may be determined in accordance with actual needs. For example, but it is not limited to that, both the first reflection layer 21 and the second reflection layer 22 have 50 layers, etc., wherein the first reflector layer 2 is a layer of Al_{y}Ga_{1-y}As, and the second reflector layer 5 is a layer of AlₓGa₁₋ₓAs, wherein, x>0.7, y<0.4. Both the substrate 1 and the first reflector layer 2 may be N-type or P-type;
Forming an oxidation layer 3 on the first reflector layer 2, and forming the light-emitting layer 4 on the oxidation layer 3. Of course, the light-emitting layer 4 may be alternatively formed on the first reflector layer 2, and the oxidation layer 3 formed on the light-emitting layer 4. Further alternatively, the oxidation layer 3 may be formed on the first reflector layer 2, the light-emitting layer 4 on the oxidation layer 3, and another oxidation layer 3 also on the light-emitting layer 4. The light-emitting layer 4 at least comprises Multiple Quantum Well (MQW) layers which are stacked. The Multiple Quantum Well (MQW) layers consist of GaAs, AlGaAs, GaAsP and InGaAs layers which are stacked. The light-emitting layer 4 is used to converse the electricity to light energy. Certainly, in some examples, it may replace the Multiple Quantum Well (MQW) layer with a Single Quantum Well layer;
Forming a second reflector layer 5 on the light-emitting layer 4. The second reflector layer 5 may comprise a first reflection layer 21 and a second reflection layer 22 which are stacked. The specific layer number of the first reflection layers or the second reflection layers may be determined in accordance with actual needs. For example, but it is not limited to that, both the first reflection layer 21 and the second reflection layer 22 have 50 layers, etc., wherein the first reflector layer 2 is a layer of Al_{y}Ga_{1-y}As, and the second reflector layer 5 is a layer of AlₓGa₁₋ₓAs, wherein, x>0.7, y<0.4. When the first reflector layer 2 is a N-type, the second reflector layer 5 is a P-type; correspondingly, when the first reflector layer 2 is a P-type, the second reflector layer 5 is a N-type.

S2: Performing oxidation on the oxidation layer 3; for example, it may perform oxidation on the oxidation layer 3 by adopting the following processes:

Carrying out the etching between the adjacent light-emitting regions S and from the second reflector layer 5 to the first reflector layer 2 in an etching way. The etching at least forms an oxidation groove 6 which cuts through to the top of the first reflector layer 2. Then, using a wet oxidation process in the oxidation groove 6, it forms an oxidized region 32 inwards from the oxidation groove 6, and the oxidized region 32 surrounds an unoxidized region 31. That is, when performing the wet oxidation process, the oxidized part gradually spreads inwards from the oxidation groove 6 (in X-axis direction in FIG. 1) on the oxidation layer 3, and forms an oxidized region 32 having a preset width; the remaining part is not oxidized, and the unoxidized region 31 is used to define an exit window of a laser. The laser light emitted from the light-emitting layer 4 irradiates from the exit window to outside. During the oxidation process, the second reflection layer 22 shall receive the laser light, and form a groove 221 at the side thereof from the oxidation groove 1 and in a direction away from the oxidation groove 6. In X-axis direction, the depth D1 of the groove 221 is less than the oxidation depth D2 of the oxidized region 32.

S3: Forming an electrode 7 on the second reflector layer 5;

The electrode 7, for example, but is not limited to a ring electrode, which forms a ring surrounding the light-emitting region S.

S4: Depositing a protection layer 8;

With regard to the surface of the laser precursor on which electrodes are formed, a silica layer may be deposited as a protection layer 8 on the laser precursor through an vapor deposition process, and the protection layer 8 covers at the top of the precursor and the inner wall of the oxidation groove 6. The groove 221 is filled with a part of the protection layer 8, wherein In the vapor deposition process, the operation temperature is 200° C., and the operation pressure is 0.8 hPa. For the convenience of electrically connection, the above electrode is exposed from the protection layer 8.

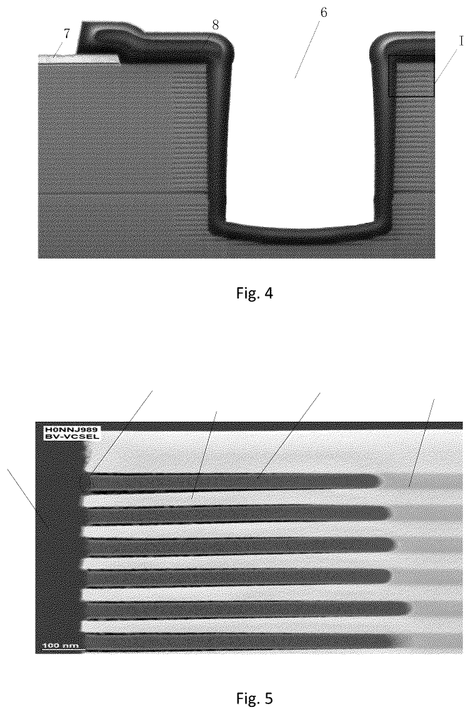

In order to verify the effects achieved by the above technical solutions of the present disclosure, the vertical cavity surface emitting laser provided by the present disclosure is observed by an electron microscope. As shown in FIG. 4 and FIG. 5, after the formation of a protection layer 8, the groove 221 is fully filled with a part of the protection layer 8 at the edge of the second reflection layer 22, and supports the edge of the first reflection layer 21, thereby enhancing the reliability of the vertical cavity surface emitting laser.

It should be understood that, The orientation or position relationships indicated by “center”, “Longitudinal”, “transverse”, “upper”, “lower”, “front”, “back”, “left”, “right”, “vertical”, “horizontal”, “top”, “bottom”, “inside”, “outside”, etc. are based on the orientation or position relationship shown in the attached drawings, which is only benefit for describing and simplifying the description of the present disclosure, rather than indicating or implying that the referred device or element must have a specific orientation or be constructed and operated in a specific orientation, therefore it cannot be understood as a limitation to the present disclosure. Furthermore, the terms “first” and “second” are used for description purposes only, and cannot be understood as indicating or implying relative importance or as implicitly indicating the number of the indicated technical features. Thus, those features defined by “first” or “second” may explicitly or implicitly include one or more of the indicated features. In the description of the present disclosure, “a plurality of” means two or more than two, unless otherwise specified.

The above description only recites better embodiments of the present application and an explanation of the technical principles used in the present application. The person skilled in the field shall understand that, the scope of invention in this application shall not be limited to technical solutions resulting from a particular combination of such technical characteristics, but shall also cover other technical solutions resulting from any combination of such technical features or their equivalent features, without departing from the conception of the present disclosure, for example, a technical scheme formed by replacing the above features with the technical features having similar functions (but not limited to) disclosed in this application.

What is claimed is:

1. A vertical cavity surface emitting laser, comprising:
a laser precursor, wherein the laser precursor comprises a first reflector layer, an oxidation layer, a light-emitting layer and a second reflector layer which are stacked, the laser precursor further comprises two or more light-emitting regions, an oxidation groove is provided between at least adjacent light-emitting regions, and the oxidation groove cuts through at least from the top of the laser precursor to the top of the first reflector layer;
wherein the second reflector layer comprises a plurality of first reflection layers and a plurality of second reflection layers, the first reflection layers and the second reflection layers are stacked alternately, and a groove is formed on the side of the second reflection layer from the oxidation groove and in a direction away from the oxidation groove; and
a protection layer which is arranged on the laser precursor, and the protection layer at least covers the inner wall of the oxidation groove, and the groove is filled with a part of the protection layer.

2. The vertical cavity surface emitting laser according to claim 1, wherein the groove is completely filled with the protection layer.

3. The vertical cavity surface emitting laser according to claim 1, wherein the protection layer is a silica protection layer or a silicon nitride protection layer.

4. The vertical cavity surface emitting laser according to claim 1, wherein both the first reflection layer and the second reflection layer are aluminum gallium arsenide reflection layers, and the aluminum content of the second reflection layer is greater than that of the first reflection layer.

5. The vertical cavity surface emitting laser according to claim 1, wherein the oxidation layer comprises an unoxidized region and an oxidized region surrounding the unoxidized region, the unoxidized region is arranged in one-to-one correspondence with the light emitting region;
in the depth direction of the groove, the depth of the groove is less than the oxidation depth of the oxidation region.

6. The vertical cavity surface emitting laser according to claim 1, wherein, the depth of each groove is the same or different.

7. The vertical cavity surface emitting laser according to claim 1, wherein, the thickness of each first reflective layer or each second reflective layer is the same or different.

8. A manufacturing method for the vertical cavity surface emission laser according to claim 1, comprising the following steps:
providing a laser precursor, wherein the laser precursor comprises a first reflector layer, an oxidation layer, a light-emitting layer and a second reflector layer which are stacked, the laser precursor comprises two or more light-emitting regions; the second reflector layer comprises a plurality of first reflection layers and a plurality of second reflection layers, the first reflection layers and the second reflection layers are stacked alternately;
forming an oxidation groove between at least adjacent light-emitting regions by etching, the oxidation groove cuts through at least from the top of the laser precursor to the top of the first reflector layer;
performing oxidation on the oxidation layer in the oxidation groove, so as to form an unoxidized region and an oxidized region surrounding the unoxidized region, and forming a groove on the side of the second reflection layer, from the oxidation groove and in a direction away from the oxidation groove;
arranging a protection layer on the laser precursor through a vapor deposition process, wherein the protection layer at least covers the inner wall of the oxidation groove, and the groove is filled with a part of the protection layer; In the vapor deposition process, the operation temperature is from 180° C. to 220° C., and the operation pressure is 0 hPa-1 hPa.
